(19) United States
(12) Patent Application Publication
(10) Pub. No.: US 2024/0086595 A1
(43) Pub. Date: Mar. 14, 2024

(54) Systems, Methods, and Apparatus For Synchronizing Digital Twins

(71) Applicant: The Boeing Company, Chicago, IL (US)

(72) Inventors: Liessman E. Sturlaugson, Chicago, IL (US); Peter G. Rhodes, Chicago, IL (US); Daniel M. Newman, Chicago, IL (US)

(21) Appl. No.: 17/943,910

(22) Filed: Sep. 13, 2022

(51) Int. Cl. G06F 30/27; G06F 30/15; G06F 30/25

(52) U.S. Cl. CPC G06F 30/27; G06F 30/15; G06F 30/25

(57) ABSTRACT

The present application relates to a system comprising a processor configured to execute a digital system model based on simulated conditions to generate simulated data. The processor may also be configured to train a surrogate model using at least the simulated data to approximate the digital system model of the system and generate, using the trained surrogate model, estimated values for conditions or parameters of the systems based on operational data, wherein the operational data includes sensor data or in-service data from the system. Further, the processor may be configured to execute the digital system model of the system to generate simulation data based on the operational data and the estimated values or parameters generated by the surrogate model and synchronize or update a digital twin of the system based on the simulation data, wherein the digital twin represents a state or condition of the system.

### FIELD

The present disclosure relates generally to vehicle systems, and more particularly synchronizing or updating a digital twin of a system or physical asset.

### BACKGROUND

This background description is provided for the purpose of generally presenting the context of the disclosure. Unless otherwise indicated herein, material described in this section is neither expressly nor impliedly admitted to be prior art to the present disclosure or the appended claims.

Vehicles may include various systems or subsystems that provide designated functions for a vehicle. For example, a typical aircraft includes numerous subsystems (such as flight control systems, radar systems, air conditioning units, air intakes, blowers, electronics, and the like) positioned throughout the aircraft. At least some of the subsystems may be vital to the performance or intended flight or mission of the aircraft. For example, an aircraft may include radar electronics in a forward portion of the fuselage and hydraulic and pneumatic systems throughout the fuselage. Various military aircraft may include a broad suite of systems and electronics, many of which are mission and/or flight critical systems.

Operative subsystems of a vehicle may be monitored over time to determine whether or not they are functioning properly. Each operative subsystem may be monitored in order to determine actual or potential failures and/or malfunctions. For example, internal diagnostic checking routines, such as built-in self-test routines, may be executed by computers to provide the states or conditions of the operative subsystems. As can be appreciated, a typical aircraft includes numerous operative subsystems. As such, the process of generating and updating the state or condition of each operative sub-system may be time-consuming and labor-intensive.

Physics or model-based methods may be used to generate a state or condition of an operative subsystem of an aircraft. These types of methods attempt to understand the physical model of the operative subsystem and determine expected values in normal operating conditions. An alert may be output if sensor readings deviate from the expected values. For example, active channels of an aircraft controller may be monitored through the use of rules generated by a logic table that includes or is correlated with expected values. If a fault is detected, the model-based methods may output a sequence of action or maintenance items. However, it may be time consuming to execute physics-based models to generate and update a state or condition of large and/or a complex systems of an aircraft.

In another model-based method, state space models along with Kalman filtering may be used to generate and update a state or condition of an operative subsystem. However, in such a model-based method, a large number of channels may be monitored, which may increase the complexity and cost of the model-based methods. Further, when a component is changed or upgraded, new models typically need to be generated.

Operative subsystems may also be monitored through pattern recognition methods. However, pattern recognition methods for monitoring the state or condition of a subsystem of an aircraft typically require large amounts of training data in order to accurately generate and update the state of the subsystem. Further, when a subsystem that is being monitored undergoes a change (such as a system upgrade), the pattern recognition model or method may need to be re-trained.

As complex systems become more integrated, traditional analysis methods to monitor and update the state or condition of a system or subsystem may no longer be practical in terms of breadth of coverage and labor costs involved. Accordingly, a need exists for a system and method to facilitate updating the state or condition the operative subsystems of a vehicle.

### SUMMARY

The present application discloses embodiments that relate to systems, methods, and apparatus for synchronizing or updating a digital twin of a subsystem (e.g., system) or a physical asset of a vehicle. As an example, the subsystem may include a physical asset of an aircraft, such as an environmental control system, a propulsion system, or the like. To monitor or track a state or condition of the subsystem, the embodiments of the present application may be configured to generate a digital twin of the subsystem. The digital twin may be a digital or virtual representation of a state or condition of the subsystem. For example, the digital twin may be a representation of an operational or performance state of the subsystem.

The digital twin of the subsystem may be updated or synchronized by executing a digital system model of the subsystem. To update or synchronize the digital twin to correspond to the current state of the subsystem, a surrogate model of the digital system model may trained with simulated data generated by the digital system model. The surrogate model may be executed to generate estimates of parameters or variables of the subsystem based on operational or performance data (e.g., in-service data) of the subsystem. Further, the digital system model of the subsystem may be executed to generate output or simulation data for updating the digital twin of the subsystem based on operational or performance data and the estimates of the parameters or variables generated by the surrogate model. The digital twin may be updated or synchronized based on the simulation data generated by the digital system model of the subsystem. By using the estimates of the parameters or variables of the subsystem generated by the surrogate model, the digital system model of the subsystem may be executed more quickly and efficiently to update the digital twin of the subsystem of the vehicle.

In one aspect, the present application discloses a system comprising a processor in communication with a memory. The processor may be configured to receive a digital system model of a system of a vehicle and execute the digital system model based on simulated conditions to generate simulated data. The processor may also be configured to train a surrogate model using at least the simulated data to approximate the digital system model of the system and generate, using the trained surrogate model, estimated values for conditions or parameters of the systems based on operational data, wherein the operational data includes sensor data or in-service data from the system. Further, the processor may be configured to execute the digital system model of the system to generate simulation data based on the operational data and the estimated values or parameters generated by the surrogate model and synchronize or update a digital twin of the system based on the simulation data, wherein the digital twin represents a state or condition of the system.

In another aspect, the present application disclosed a method. The method may comprise receiving a digital system model representing a system of a vehicle and executing the digital system model based on simulated conditions to generate simulated data. The method may also comprise training a surrogate model using at least the simulated data to approximate the digital system model and generating, using the trained surrogate model, estimated values for conditions or parameters of the system based on operational data, wherein the operational data includes sensor data or in-service data from the system. Further, the method may comprise executing the digital system model of the system to generate simulation data based on the operational data and the estimated values for the conditions or parameters generated by the surrogate model and synchronizing or updating a digital twin of the system based on the simulation data, wherein the digital twin represents a state or condition of the system.

In still another aspect, a non-transitory computer-readable medium having stored thereon instruction code is disclosed, wherein the instruction code is executable by a processor of a computer to perform operations. The operations may comprise receiving a digital system model representing a system of a vehicle and executing the digital system model based on simulated conditions to generate simulated data. The operations may also comprise training a surrogate model using at least the simulated data to approximate the digital system model and generating, using the trained surrogate model, estimated values for conditions or parameters of the system based on operational data, wherein the operation data includes sensor data or in-service data from the system. Further, the operations may comprise executing the digital system model of the system to generate simulation data based on the operational data and the estimated values for the conditions or parameters generated by the surrogate model and synchronizing or updating a digital twin of the system based on the simulation data, wherein the digital twin represents a state or condition of the system.

The foregoing summary is illustrative only and is not intended to be in any way limiting. In addition to the illustrative aspects, embodiments, and features described above, further aspects, embodiments, and features will become apparent by reference to the figures and the following detailed description.

### BRIEF DESCRIPTION OF THE DRAWINGS

A more complete understanding of embodiments of the present application may be derived by referring to the detailed description and claims when considered in conjunction with the following figures, wherein like reference numbers refer to similar elements throughout the figures. The figures are provided to facilitate understanding of the disclosure without limiting the breadth, scope, scale, or applicability of the disclosure. The drawings are not necessarily made to scale.

FIG. 1 illustrates a block diagram of an operational environment, according to an example implementation.

FIG. 2 illustrates a block diagram of an aircraft, according to an example implementation.

FIG. 3 illustrates a schematic representation of an environmental control system of an aircraft, according to an example implementation.

FIG. 4 illustrates a block diagram of a digital twin system, according to an example implementation.

FIG. 5 illustrates a block diagram of a digital system model, according to an example implementation.

FIG. 6 illustrates a comparison of the execution times of models of a subsystem.

FIG. 7 illustrates a block diagram of another digital system model, according to an example implementation.

FIG. 8 illustrates a block diagram of a method, according to an example.

### DETAILED DESCRIPTION

The following detailed description describes various features and functions of the illustrative systems, methods, and apparatus with reference to the accompanying figures. The following detailed description is exemplary in nature and is not intended to limit the disclosure or the application. Descriptions of specific systems, methods, apparatus, and techniques are provided only as examples. It may be readily understood that certain aspects of the illustrative systems, methods, and apparatus can be arranged and combined in a wide variety of different configurations, all of which are contemplated herein. Thus, other embodiments can be utilized and other changes can be made without departing from the scope of the subject matter presented herein.

The present application discloses embodiments that relate to systems, methods, and apparatus for synchronizing or updating a digital twin of a subsystem of a vehicle. As an example, the subsystem may include a physical asset of an aircraft, such as an environmental control system, a propulsion system, or the like. To monitor or track a state or condition of the subsystem, the embodiments of the present applications may be configured to generate a digital twin of the subsystem. The digital twin may be a digital or virtual representation of a state or condition of the subsystem. For example, the digital twin may be a representation of an operational or performance state of the subsystem of the vehicle.

The digital twin of the subsystem may be updated or synchronized by executing a digital system model of the subsystem. To update or synchronize the digital twin to correspond to the current state of the subsystem, a surrogate model of the digital system model may trained with simulated data generated by the digital system model. The surrogate model may be executed to generate estimates of parameters or variables of the subsystem based on operational or performance data of the subsystem. Further, the digital system model of the subsystem may be executed to generate output or simulation data for updating the digital twin of the subsystem based on operational or performance data and the estimates of the parameters or variables of the subsystem generated by the surrogate model. The digital twin may be updated or synchronized based on the output or simulation data generated by the digital system model of the subsystem. By using the estimates of the parameters or variable generated by the surrogate model, the digital system model of the subsystem can be executed more quickly and efficiently to update the digital twin of the subsystem.

The digital twin of the subsystem may enable the state or condition (e.g., the performance or operational characteristics) of the subsystem to be monitored. For example, a computer system may monitor the state or condition of the subsystem based on the digital twin of the subsystem. The computing system may access or analyze the digital twin to determine the existence of impending or potential faults within the subsystem of the vehicle. When a fault of the subsystem is identified by the computer system, an operator and/or service personnel may be notified and maintenance may be scheduled.

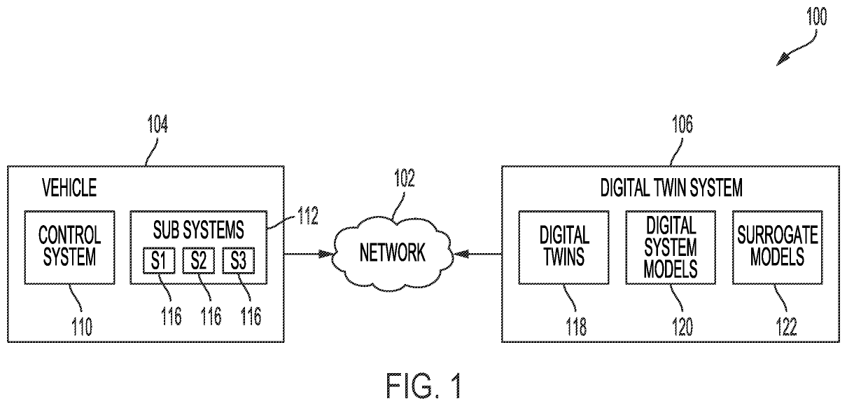

Referring now to the Figures, FIG. 1 is a block diagram of an operating environment 100 in which embodiments of the present application may be implemented. As shown in FIG. 1, the operating environment 100 includes a network 102, a vehicle 104, and a digital twin system 106. The vehicle 104 is communicatively coupled to the network 102 and may exchange information with the digital twin system 106. The operating environment 100 may also include server computers, client computers, additional vehicles, and other devices (not shown) communicatively coupled to network 102. For example, the operating environment may include a client computer operatively coupled to the network 102 to enable an operator to input information into the digital twin system 106 and to receive information from the digital twin system 106.

The vehicle 104 of the operating environment 100 may include a control system 110 or monitoring system and one or more subsystems 112 located throughout, on, or within the vehicle 104. The subsystems 112 may be operatively connected to the control system 110. The subsystems 112 may control, perform, and/or monitor one or more aspects of the operation of the vehicle 104. Each subsystem 112 may be an electronic, mechanical, and/or hardware sub-system. For example, if the vehicle 104 is an aircraft, the subsystems 112 may include an environmental control system, a propulsion system, a flight control system, an electrical system, a hydraulic system, a pneumatic system, and/or any other aircraft system. If the vehicle 104 is an automobile, for example, the subsystems 112 may include a fuel-monitoring system, a tire pressure monitoring system, an oil monitoring system, an air conditioning system, an engine control system, and/or any other automotive system. As such, the subsystems 112 may include any system, hardware, equipment, or the like of the vehicle that can be monitored or analyzed.

The subsystems 112 may be a portion of other systems or subsystems of the vehicle 104. For example, a subsystem may be a bleed air system which is a subsystem of an environmental control system. Each of the subsystems 112 may include one or more components (not shown) for performing one or more functions of the subsystem 112. The components may be electrical, optical, mechanical, hydraulic, fluidic, pneumatic, and/or aerodynamic components. For example, the components may be electro-mechanical components such as a motor, an actuator, a valve, a pump, an actuator, or a battery. The components may be referred to as parts, elements, modules, units, etc., and may be line replaceable units and/or field replaceable units. The components may be subsystems 112 of a respective subsystem. The components may be active and/or controlled components (i.e., components configured to change state during operation of the vehicle 104).

The subsystems 112 of the vehicle 104 may include one or more sensors 116 operably connected with the control system 110. The sensors 116 may be configured to measure and/or monitor the performance of individual components, groups of components, and/or the subsystems 112. For example, the sensors 116 may be configured to sense or monitor operational or performance data (e.g., operational parameters or variables) of the subsystems 112. The operational or performance data may include any attribute, condition, feature, behavior, or the like that may change over time, such as voltage, current, fluid pressure (e.g., air pressure), temperature, and the like. As shown, the subsystems 112 may include three sensors 116, but each subsystem 112 may include any number of sensors. Additionally or alternatively, the sensors 116 may measure and/or monitor the environmental conditions and/or the inputs/outputs of the subsystems 112. The sensors 116 may also be utilized in built-in testing, performance monitoring, and/or subsystem control.

The control system 110 of the vehicle 104 is in communication with the sensors 116 of the subsystems 112. For example, the sensors 116 may be in communication with the control system 110 through wired and/or wireless connections or links. The control system 110 may be configured to receive and collect sensor data (e.g., in-service or raw data) from the sensors 116 during operation of the vehicle 104. The sensor data may include information (e.g., operational or performance data) relating to environmental conditions (e.g., temperature, pressure, and humidity), vehicle or aircraft operation (e.g., airspeed, altitude, ground location, and angle of attack), subsystem operation, subsystem command status, component operation, and/or component command status. When the vehicle 104 is an aircraft, the sensor data may be referred to as flight data, which may be collected over multiple flights.

After receiving the sensor data from the sensors 116, the control system 110 of the vehicle 104 may prepare the sensor data for analysis or data processing. For example, the control system 110 may organize, format, and/or filter the sensor data to remove irrelevant and/or faulty data. The control system 110 may also calculate statistics based on the sensor data and the statistics may be analyzed or monitored for fault detection. As such, the control system 110 may pre-process the sensor data received from the sensors 116 of the subsystems 112. The pre-processed data, such as in the form of a statistical overview, may then be analyzed by the control system 110 to determine the existence of impending faults within the subsystems 112. The control system 110 may be configured to store the processed sensor data (e.g., operational or performance data) and/or send the processed sensor data to the digital twin system 106.

The control system 110 may be or include one or more computers, control units, circuits, or the like, such as processing devices, that may include one or more microprocessors, microcontrollers, integrated circuits, and the like. While shown within the vehicle 104, the control system 110 may be remotely located from the vehicle 104. For example, the control system 110 may be at a central or off-board monitoring site. The control system 110 may also include memory, such as non-volatile memory, random access memory, and/or the like. The memory may include any suitable computer-readable media used for data storage. The computer-readable media may be configured to store information that may be interpreted or analyzed by the control system 110. The information may be data or may take the form of computer-executable instructions, such as software applications, that cause a microprocessor or other such control unit within the control system 110 to perform certain functions and/or computer-implemented methods.

The computer-readable media of the memory may include computer storage media. The computer storage media may include volatile and non-volatile media, removable and non-removable media implemented in any method or technology for storage of information such as computer-readable instructions, data structures, program modules or other data. The memory and/or computer storage media may include, but are not limited to, RAM, ROM, EPROM, EEPROM, or other solid state memory technology, CD-ROM, DVD, or other optical storage, magnetic cassettes, magnetic tape, magnetic disk storage or other magnetic storage devices, or any other medium which may be used to store desired information (e.g., sensor or flight data) and that may be accessed by the control system 110.

Referring still to FIG. 1, the digital twin system 106 of the operating environment 100 is communicatively coupled to the network 102 and may exchange information with the control system 110 of the vehicle 104. The digital twin system 106 may include or represent one or more processors (e.g., microprocessors, field programmable gate arrays, application specific integrated circuits, multi-core processors, or other electronic circuitry) that implement instructions of a computer program by carrying out arithmetic, logical, control, and/or input/output operations specified by the instructions. For example, the digital twin system 106 may include a cluster of interconnected or intercommunicating computers. Further, the digital twin system 106 may be implemented in the cloud. For example, the digital twin system 106 may include components in a cloud architecture that is accessed by a client computer system over the Internet.

The digital twin system 106 of the operating environment 100 may be remotely located from the vehicle 104 (e.g., an off-board system). For example, the digital twin system 106 may be located at a central or fixed land-based location. When the digital twin system 106 is remotely located from the vehicle 104, the digital twin system 106 may be associated with a plurality of vehicles (e.g., a fleet of vehicles). In some embodiments, the digital twin system 106 may be located within the vehicle 104. For example, the digital twin system 106 may be a part of the vehicle 104 (an on-board system, also referred to as an on-platform system).

The digital twin system 106 may be configured to receive information from the control system 110 of the vehicle 104. For example, the digital twin system 106 may receive sensor data from the sensors 116 of the subsystems 112 of the vehicle 104. The sensor data may include operational or performance data (e.g., operational parameters or variables) associated with the subsystems 112 of the vehicle 104. The operational or performance data may be indicative or representative of the states or conditions of the subsystems 112 of the vehicle 104. For example, the operational or performance data may include any attribute, condition, feature, behavior, characteristic, or the like that may change over time, such as voltage, current, fluid pressure (e.g., air pressure), temperature, and the like.

As shown in FIG. 1, the digital twin system 106 of the operating environment 100 may generate or receive digital twins 118 of the subsystems 112 or physical assets of the vehicle 104. The digital twins 118 may be developed or generated during the design, testing, manufacturing, or operational phase of the subsystem. In some instances, the digital twin system 106 may generate a digital twin of the subsystem based on the sensor data (e.g., in-service data) received from the vehicle 104. For example, the digital twin system 106 may execute digital system models of the subsystems to generate the digital twins 118 of the subsystems of the vehicle 104.

The digital twins 118 may be a digital or virtual representations of states or conditions of the subsystems 112 of the vehicle 104. For example, the digital twins 118 may represent the subsystems 112 of the vehicle 104 based on its current operational states or conditions. In some instances, the digital twin system 106 may include multiple digital twins representing a plurality of different systems, subsystems, and/or components of the vehicle 104. For example, the digital twin system 106 may include a digital twin of an environmental control system (ECS) of the vehicle 104 as further described below.

As shown in FIG. 1, the digital twin system 106 may also include digital system models 120 of the subsystems 112 of the vehicle 104. In some embodiments, the digital system models 120 may be high-fidelity models and/or physics-based models. For example, when the vehicle 104 is an aircraft, the digital system models 120 may model or represent an airframe, a hydraulic system, an environmental system, a flight management system, a navigation system, a communications system, a sensor system, or some other system, subsystem, or component of the aircraft. The digital system models 120 of the digital twin system 106 may be configured to simulate the operation or performance of the subsystems 112 of the vehicle 104 based on a given set of conditions or parameters. For example, the digital system models 120 may be executed to generate output or simulation data for the digital twin (e.g., states or conditions of the subsystems) based on actual or historical data detected by the sensors 116 of the vehicle 104 and inputs from a surrogate model as further described below. The digital twin system 106 may update or synchronize the digital twins 118 based on the states or conditions of the subsystems generated by the digital system models 120 of the subsystems 112.

The digital twin system 106 may also generate or receive surrogate models 122 of the digital system models 120 associated with the subsystems 112 of the vehicle 104. The surrogate models 122 may be low-fidelity, computationally efficient, and/or physical-based models that approximate the behavior of the subsystems 112 of the vehicle 104 as further described below. The digital twin system 106 may execute the surrogate models 122 based on actual or historical data detected by the sensors (e.g., actual or in-service data) of the vehicle 104 to generate estimates of one or more parameters or variables of the subsystems 112 of the vehicle 104. For example, the surrogate models may be configured to generate estimates of unobservable conditions of the subsystems (e.g., conditions of the subsystems that may not be directly measured or detected by a sensor).

Further, the digital twin system 106 may execute the digital system models to generate output or simulation data (e.g., states or conditions of the subsystem) based on the estimates of the parameters and variables generated by the surrogate model and the sensor data (e.g., actual or in-service data) received from the sensors 116 of the subsystems 112 to quickly and efficiently update or synchronize the digital twin of the subsystems 112 of the vehicle 104. The digital twin system 106 may update or synchronize the digital twins 118 of the subsystems 112 to correspond to the current states or conditions of the subsystems 112 based on the output or simulation data generated by the digital system models 120.

The digital twin system 106 may also monitor the state or condition of the subsystems 112 of the vehicle 104 based on the digital twins 118 of the subsystems 112. When the digital twin system 106 determines a fault or degraded condition or state of a subsystem based on the digital twins of the subsystems 112, the digital twin system 106 may take a responsive action, such as by scheduling maintenance for the vehicle 104, notifying an operator, or the like.

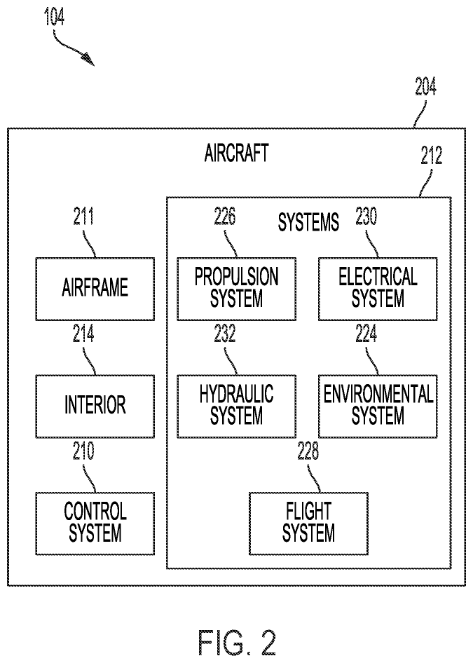

FIG. 2 illustrates a block diagram of the vehicle 104 of FIG. 1. The vehicle 104 may be an aircraft 204, such as a commercial or military jet. In other embodiments, the vehicle 104 may be a land-based vehicle, a boat or water-based vehicle, an aerospace vehicle, or any other vehicle. As shown in FIG. 2, the aircraft 204 may include a control system 210 or monitoring system, an airframe 211, an interior 214, and a plurality of subsystems 212 or systems, each of which may include one or more sensors. The subsystems 212 can control, perform, and/or monitor one or more aspects of the operation of the aircraft 204. The subsystems 212, which also may be referred to as systems, include an environmental system 224, a propulsion system 226, a flight system 228, an electrical system 230, and a hydraulic system 232. The subsystems 212 may be a portion of other systems or subsystems of the aircraft 204. For example, the environmental system 224 may include an environmental control system (ECS) that is a subsystem of the flight system 228. The subsystems 212 may also include a guidance system, a navigation system, and any other aircraft system.

Each of the subsystems 212 may include one or more components (not shown) that together may perform the functions of the subsystems 212. The components may be electrical, optical, mechanical, hydraulic, fluidic, pneumatic, structural, and/or aerodynamic components. For example, the components may include actuators, servomechanisms, engines, motors, electronics modules, pumps, valves, and airframe members. The components may be associated with external portions of the aircraft 204 such as flight control surfaces, landing gear, etc. The components may be referred to as parts, elements, units, etc., and may be line replaceable units and/or field replaceable units. The components may be subsystems of a respective system. The components may be active and/or controlled components (e.g., components may be configured to change state during flight of the aircraft).

The subsystems 212 may include one or more sensors (not shown) configured to measure and/or monitor the performance of the individual components, groups of components, and/or the subsystems 212 during flight of the aircraft 204. The sensors may include encoders, accelerometers, position sensors, electrical meters, electronic compasses, strain gauges, temperature sensors, and/or pressure transducers. Additionally or alternatively, the sensors may be configured to measure and/or monitor environmental conditions (e.g., temperature, pressure, humidity), aircraft operation (e.g., airspeed, altitude, ground location, heading), flight performance (e.g., acceleration, strain, velocity, pitch rate, roll rate, yaw rate, angle of attack, attitude, etc.), subsystem operation, subsystem command status, operational states of the subsystem of the aircraft, conditions of one or more components, and/or inputs and/or outputs of the subsystems 212. The sensors may be utilized in built-in testing, performance monitoring, and/or subsystem control.

The control system 210 of the aircraft 204 may be configured to control and/or monitor one or more of the subsystems 212, components, and/or sensors. The control system 210 may be arranged within or onboard the aircraft 204 and can be in communication with each of the subsystems 212. The control system 210 may be configured to store and access sensor data and/or flight data of the subsystems 212. The sensor and flight data may be at least partially stored in the control system 210 and/or a memory device. The sensor and flight data may include information from more than one flight of the aircraft and may include flight information from a plurality of aircraft (e.g., a fleet of aircraft).

The control system 210 of the aircraft 204 may also be configured to communicate with the digital twin system 106 of FIG. 1. The control system 210 may include one or more computers, control units, circuits, or the like, such as processing devices, that may include one or more microprocessors, microcontrollers, integrated circuits, and the like. While shown within the aircraft 204, the control system 210 may be remotely located from the aircraft 204. For example, the control system 210 may be located at a central or off-board monitoring site. The control system 210 may also include memory, such as non-volatile memory, random access memory, and/or the like. The memory may include any suitable computer-readable media used for storing data as further described above.

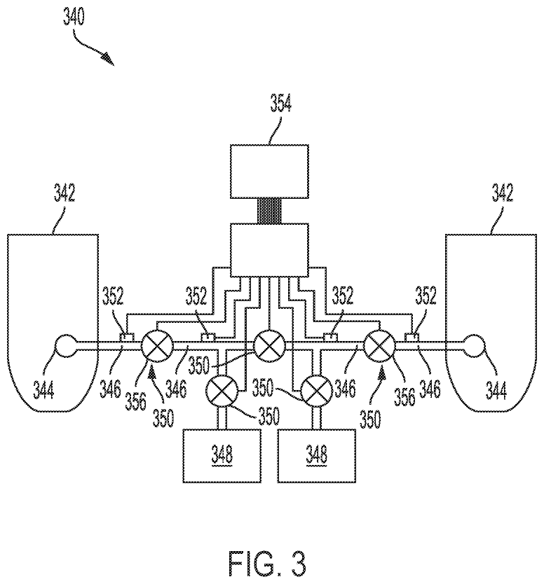

FIG. 3 schematically represents an environmental control system 340, which is one of several subsystems on a typical aircraft. The environmental control system 340 includes electronic, fluidic, pneumatic, and mechanical components. The environmental control system 340 may be configured to circulate air and to regulate the temperature and/or pressure of pressurized compartments of the aircraft, for example regulating the temperature and/or pressure of the cockpit and/or cabin. Additionally, the environmental control system 340 may be configured for avionics cooling, smoke detection, fire suppression, and cooling/heating and/or pressurization of other subsystems.

In an aircraft, high pressure air is tapped (or bled) from one or more compressor stages of the engines 342. The air is tapped at a compressor air tap 344 to form a bleed air stream. The temperature and pressure of the bleed air depends on the engine operation (e.g., the revolutions per minute) and the compressor stage. The bleed air is ducted through a bleed air conduit 346 to one or more air conditioning systems 348 which adjust the pressure and/or temperature of the compressed air before transmitting the air to the pressurized compartments. The environmental control system 340 may receive compressed air from all engines 342 of a multi-engine aircraft, for example from the right engine and the left engine. Pressure regulation, balancing, etc., may be controlled by one or more components 350 as the bleed air is transmitted to the one or more air conditioning systems 348. Examples of components of environmental control system 340 include valves, regulators, shutoff valves, non-return valves, overpressure switches, relief valves, heat exchangers, water filters, air filters, and the air conditioning systems 348.

In aircraft with multiple engines, the environmental control system 340 may include separate air conditioning systems configured primarily to operate with the bleed air from different engines. The environmental control system 340 may be configured to equalize, mix, or otherwise combine the air from each engine 342 before transmitting the air to the air conditioning systems 348.

The environmental control system 340 may include one or more sensors 352 (e.g., pressure transducers, temperature sensors, and/or flow meters) configured to measure and/or monitor gas (e.g., air) and/or liquid within the environmental control system 340. For example, sensors 352 may be located upstream and/or downstream of a component (e.g., a valve, a regulator, etc.) and may be located downstream of the compressor air tap 344. The sensors 352 and the components 350 may be controlled by a controller 354, such as the control system 210 of FIG. 2, that is in electrical and/or electronic communication with the sensors 352 and/or components 350.

Within the environmental control system 340 represented in FIG. 3 are two primary bleed air pressure regulating and shutoff valves 356 each configured to restrict the bleed air flow as necessary to maintain the desired pressure and air flow to downstream systems. The shutoff valves 356 may also be referred to as manifold pressure regulating shutoff valves. The shutoff valves 356 are configured to control the bleed air flow within the associated bleed air conduit 346 and ultimately to control the input air flow to the associated air conditioning systems 348. Each bleed air conduit 346 coming from each engine 342 is instrumented with at least one of the sensor 352. The sensors 352 are configured to measure a property of the air flow upstream, downstream, and/or across the primary bleed air pressure regulating and shutoff valves 356.

If one of the primary bleed air pressure regulating and shutoff valves 356 performs unexpectedly (e.g., by opening inconsistently or incompletely) bleed air from the other engine 342 may be routed to both air conditioning systems 348 and, hence, the environmental control system 340 may continue to operate. For example, air may be rerouted around the non-performing valve and/or the environmental control system 340 may operate at reduced performance (e.g., utilizing air from just one engine). Because the environmental control system 340 may be resilient enough to continue to operate without one of the primary bleed air pressure regulating and shutoff valves 356, even complete non-performance or severe degradation may not be immediately noticed and repaired. Once a non-performing valve has been identified, the non-performing valve may be repaired as soon as possible, e.g., before the next flight.

Where it is hard to predict when a component may perform unexpectedly, the urgency to repair a non-performing component may be heightened (e.g., to avoid having a subsystem with more than one non-performing component). Further, unexpected performance of some of the components 350 may stress the respective subsystem and may contribute to and/or cause other components to perform unexpectedly. For example, a partially or completely non-performing shutoff valve in the environmental control system 340 may lead to a frozen condenser and/or a damaged air cycle machine (both components 350 of the environmental control system 340 and the air conditioning systems 348). Hence, the shutoff valve 356 typically is immediately repaired when non-performance is identified.

To monitor the state or condition of the environmental control system 340 to detect non-performing or degraded components, the controller 354 may generate or receive a digital system model, a surrogate model, and a digital twin of the environmental control system 340. The controller 354 may analyze the digital twin of the environmental control system 340 to determine the existence of non-performing components or impending faults within the environmental control system 340. The digital twin may be a digital or virtual representation of the state or condition of the environmental control system 340. In some instances, the digital twin may represent the environmental control system 340 based on its current state or condition. To synchronize or update the digital twin to correspond to the current state of the environmental control system 340, the controller 354 may execute the surrogate model to generate estimates of parameter or variables associated with the environmental control system 340 based on operational or performance data (e.g., actual or in-service data) of the environmental control system 340.

Further, the controller 354 may execute the digital system model of the environmental control system 340 to generate output or simulation data (e.g., the state or condition of the environmental control system) based on actual or historical operational data generated by the sensors of the vehicle (e.g., observed input) and the estimates of the parameters or variables generated by the surrogate model (e.g., unobserved inputs). In one embodiment, the simulation data generated by the digital system model may include the state relating to heat exchanger temperatures, cabin temperatures, air cycle machine temperatures, etc. The controller 354 may update or synchronize the digital twin of the environmental control system based on the simulation data. For example, the controller 354 may update or change the digital twin to correspond to the current state of the environmental control system 340 based on the output or simulation data generated by the digital system model of the subsystem. By using the estimates of the parameters or variables generated by the surrogate model, the digital system model of the environmental control system 340 can be executed to quickly and efficiently update the digital twin of the environmental control system 340.

The controller 354 may analyze the updated digital twin of the environmental control system 340 to determine the state or condition (e.g., the performance or operational characteristics) of the environmental control system 340. For example, the controller 354 may analyze the digital twin of the environmental control system to determine the existence of impending faults within the environmental control system 340. When a fault of the environmental control system 340 is identified by the controller 354, an operator and/or service personnel may be notified and maintenance may be scheduled. Although an environmental control system 340 of an aircraft is described above, additional digital twins may be generated or received for any system, subsystem, and/or components of a vehicle. For example, the controller 354 may generate or receive a digital twin of a propulsion system.

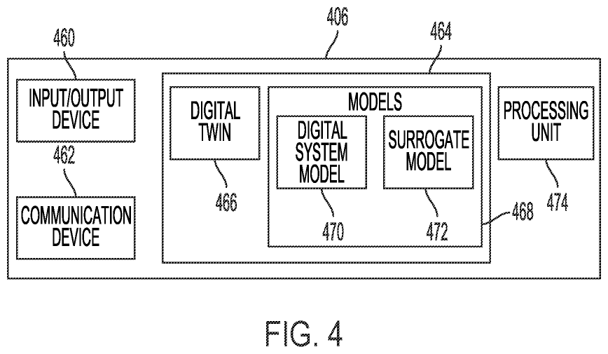

FIG. 4 illustrates a block diagram of the digital twin system 406, according to an exemplary embodiment. The digital twin system 406 may be configured to monitor, assess, track, and/or indicate the state or condition of one or more systems, subsystems, and/or components of a vehicle. For example, the digital twin system 406 may be configured to generate or receive a digital twin of a subsystem to enable the determination of the state or condition of the subsystem (e.g., current condition). The subsystem may include one of the subsystems 212 of the aircraft 204. Further, the digital twin system 406 may be configured to update or synchronize the digital twin of the subsystem. For example, the digital twin system 406 may update or synchronize the digital twin to correspond to the current state of the subsystem as further described below. The digital twin may be a digital or virtual representation of a state or condition of the subsystem. For example, the digital twin may represent an operational or performance state or condition of the subsystem of the vehicle 104. In some embodiments the digital twin represents the subsystem based on its current state or condition.

As shown in FIG. 4, the digital twin system 406 includes an input/output device 460 that allows an operator to interact with the digital twin system 406. For example, the input/output device 460 may include monitors (e.g., video monitors), displays (e.g., alphanumeric displays, lamps, a display device, and/or LEDs), keyboards, pointing devices (e.g., mice), touch screens, speakers, buzzers, and controls (e.g., buttons, knobs, etc.). For example, the operator may use the input/output device 460 of the digital twin system 406 to access or generate a digital twin of a subsystem of the vehicle 104. The operator may also use the input/output device 460 to select a digital twin of a subsystem and to input various operational parameters and/or conditions of the subsystem into the digital twin system 406.

The digital twin system 406 may also provide information to the operator about a digital twin of a subsystem of the vehicle 104. For example, the input/output device 460 of the digital twin system 406 may be configured to display characteristics of a digital twin of the subsystem of the vehicle 104. The input/output device 460 may also provide actual operational or performance data of the subsystem (as detected by the sensors) and/or simulated operational or performance data of the subsystem (as generated by a model of the subsystem) to the operator. Further, the input/output device 460 may provide maintenance actions for the operator, such as scheduling a repair of a component of the vehicle.

The digital twin system 406 may communicate with a vehicle (e.g., vehicle 104 of FIG. 1), either directly, via direct wireless transmission, or indirectly over a network (e.g., network 102). The digital twin system 406 may include a communication interface 462, which enables the digital twin system 406 to communicate with the vehicle 104. The communication interface 462 may include one or more wired, wireless, radio, optical, and/or electrical communication channels. For example, the communication interface 462 may enable information (e.g., actual or simulated operational parameters and environment conditions of a vehicle) to be received by the digital twin system 406 from the vehicle 104.

The digital twin system 406 may include a storage unit 464 or memory device. The storage unit 464 may store digital twins of subsystems of the vehicle 104. For example, the digital twin system 406 may store a digital twin 466 of a subsystem or a physical asset of the vehicle 104. The digital twin 466 of the subsystem may be a digital or virtual representation of a state or condition of the subsystem of the vehicle 104. For example, the digital twin 466 may include a representation of an operational or performance state of the subsystem. In some instances, the digital twin 466 may represent the subsystem based on its current state or condition. Further, the digital twin system 406 may include multiple digital twins representing a plurality of different systems, subsystems, and components of the vehicle (e.g., physical assets). For example, the digital twin system 406 may include a digital twin that represents the state or condition of the environmental control system 340 as shown in FIG. 3.

The storage unit 464 of the digital twin system 406 may also store the models 468 of the subsystems of the vehicle 104. Alternatively, the models 468 may be installed and stored at a separate computing device from the digital twin system 406 and the digital twin system 406 may access and/or receive the models 468 from the separate computing device. The models 468 may include digital system models of the subsystems of the vehicle 104. For example, the digital twin system 406 may store a digital system model 470 of a subsystem of the vehicle 104. The digital system model 470 may be a high-fidelity model and/or a physics-based model of the subsystem of the vehicle 104. In one example, the digital twin system 406 may store a digital system model of the environmental control system 340 as shown in FIG. 3. The digital twin system 406 may be configured to store digital system models for any system, subsystem, and/or component of the vehicle 104 as well as for systems, subsystems, and/or components of other vehicles (e.g., fleet vehicles).

The digital twin system 406 may also store surrogate models of the digital system models of the subsystems of the vehicle 104. For example, the digital twin system 406 may include a surrogate model 472 of the digital system model 470 of a subsystem. For example, the surrogate model 472 may be a low-fidelity, computationally efficient and/or a physical-based model that approximates the behavior of the subsystem. The surrogate model 472 may be built or generated using estimation algorithms for processing sensor data (e.g., operational or performance data) generated by the subsystem of the vehicle 104. For example, the surrogate model 472 may be a statistical or mathematical model that approximates the subsystem of the vehicle 104 and may be a reduced version of the digital system model 470 of the subsystem. As such, the surrogate model may include a trained machine-learning based model, a regression model, a neural network, a machine learning model, and/or one or more approximation of equations of the digital system model. In some examples, the surrogate model 472 may be generated by applying machine learning algorithms to simulated data (e.g., training data) generated by the digital system model 470 of the subsystem.

The storage unit 464 of the digital twin system 406 may include a computer hard drive, random access memory, read-only memory, dynamic random access memory, an optical drive, or the like. The storage unit 464 may store the program instructions that are carried out by processing or computing units of the digital twin system 406. Additionally, the storage unit 464 may store actual performance data (including operating parameters) and/or simulated performance data of the subsystem of the vehicle 104. For example, in one embodiment, the digital twin system 406 may be configured to receive and store actual performance data and environmental conditions regarding the operations (e.g., one or more flight) of the environmental control system 340 as shown in FIG. 3.

The digital twin system 406 may include a processing unit 474 operatively coupled to the storage unit 464. The processing unit 474 may be configured to generate or receive digital twins of subsystems or physical assets of the vehicle 104. For example, the processing unit 474 may receive or generate the digital twin 466 of the subsystem of the vehicle 104. The digital twin 466 may be developed or generated during the design, testing, manufacturing, or operational phase of the subsystem of the vehicle 104. In some instances, the processing unit 474 may generate the digital twin 466 of the subsystem or may select and/or receive the digital twin 466 from the storage unit 464 or a separate computing system. The processing unit 474 may generate or produce the digital twin based on actual or historical operational data and/or performance data (e.g., actual or in-service data) received from the subsystem. As described above, the digital twin 466 may be a digital or virtual representation of a state or condition of the subsystem of the vehicle 104. For example, the digital twin 466 may include a representation of the operational or performance state or condition of the subsystem. In some embodiments, the digital twin 466 may represent the subsystem based on its current state or condition. Further, the digital twin system 406 may generate a digital twin for any system, subsystem, and/or component of the vehicle as well as for systems, subsystems, and/or components of other vehicles (e.g., fleet vehicles).

Once the digital twin 466 of the subsystem has been generated or received, the processing unit 474 of the digital twin system 406 may synchronize or update the digital twin 466 of the subsystem of the vehicle 104. For example, the processing unit 474 may execute the digital system model 470 of the subsystem to generate output or simulation data for the digital twin 466 of the subsystem based on actual or in-service data (e.g., sensor data from the sensors) of the subsystem and estimates of one or more parameters or variable generated by the associated surrogate model as further described below. The processing unit 474 may update or synchronize the digital twin of the subsystem to correspond to the current state of the subsystem based on the simulation data generated by the digital system model 470. In one embodiment, the processing unit 474 may execute a digital system model of the environmental control system 340 of FIG. 3 to update or synchronize the digital twin of the environmental control system 340. In other embodiments, the processing unit 474 may execute a digital system model to update or synchronize the digital twin of a propulsion subsystem of the vehicle 104 or any other system or subsystems of the vehicle.

Further, the processing unit 474 of the digital twin system 406 may be configured to generate or receive digital system models of the subsystems of the vehicle 104. For example, the processing unit 474 may generate the digital system model 470 of the subsystem of the vehicle 104. The digital system model 470 of the subsystem may be a high fidelity model and/or a physics-based model of the subsystem. In one example, the digital twin system 406 may generate a digital system model for the environmental control system 340 as shown in FIG. 3. The processing unit 474 of the digital twin system 406 may generate the digital system model 470 of the subsystem using characteristic information about the subsystem, physics-based models, and/or historical data acquired by monitoring the subsystem of the vehicle. The characteristic information may represent the types of components in the subsystem, including designated performance capabilities of the components. The physics-based models may represent numerical algorithms that simulate how the components of the subsystem operate. The historical data may be acquired over time by monitoring the subsystem during operation.

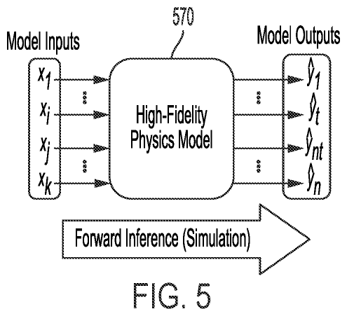

The processing unit 474 of the digital twin system 406 may execute the digital system model to generate simulated data based on operational parameters and conditions (e.g., actual or in-service data). The simulated data may represent the behavior of the subsystem of the vehicle 104. For example, the simulated data may represent the state or condition of the subsystem (e.g., an operational or performance state of the subsystem). In some instances, the processing unit 474 of the digital twin system 406 may simulate the same operation conditions that the vehicle 104 was actually exposed to during operation. In some embodiments, the processing unit 474 may use computation techniques to simulate the subsystem of the vehicle 104. As shown in FIG. 5, the processing unit 474 may execute the digital system model 570 to generate model outputs (e.g., simulated data) based on model inputs (e.g., actual or in-service data). For example, the processing unit 474 may execute the digital system model 570 to generate simulated data based on actual or historical operational or performance data received from the sensors of the subsystem. The simulated data may be used to train the surrogate model 472 of the digital system model 470 as further described below.

In some embodiments, the processing unit 474 of the digital twin system 406 may generate an executable version of the digital system model using a computer-based simulation tool (e.g., MATLAB® Simulink®, National Instruments® LABVIEW™, etc.). For example, the processing unit 474 may generate a Simulink executable version of the subsystem of the vehicle 104. In some examples, the subsystem may include an environmental control system (e.g., a 737 environmental control system) of an aircraft. The Simulink executable version of the environmental control system may be executed to generate simulated data. The simulated data may include heat exchanger temperatures, cabin temperature, air cycle machine temperatures, and the like. The execution of the Simulink executable version of the environment control system of the aircraft may take about 20 seconds to run for a single flight.

To reduce the time to simulate the environmental control system of the aircraft, the processing unit 474 of the digital twin system 406 may export the Simulink executable version of the digital system model for the environmental control system to run in a Hadoop/Spark computational environment. The Hadoop/Spark computational environment provides an open-source software framework for storage and large-scale processing of data-sets on clusters of hardware. For example, the processing unit 474 may export the Simulink executable version of the environmental control system to a Hadoop/Spark executable version of the environmental control system. The processing unit 474 can execute the Hadoop/Spark executable version of the digital system model of the environmental control system in the Hadoop/Spark computational environment. The Hadoop/Spark executable version of the digital system model can be executed faster than the Simulink execution version. For example, the processing unit 474 can execute the Hadoop/Spark executable version of the digital system in less than 20 seconds for a single flight. The processing unit 474 may execute the Hadoop/spark executable version based on operational parameters and conditions (e.g., actual or simulation data) of the environmental control system to generate simulated data for training a surrogate model of the environmental control model as further described below.

The processing unit 474 of the digital twin system 406 may also generate or receive surrogate models of the digital system models of the subsystems. For example, the processing unit 474 may generate or receive the surrogate model 472 of the digital system model 470 associated with the subsystem of the vehicle 104. In one embodiment, the processing unit 474 may generate a surrogate model 472 for the digital system model 470 of the environmental control system 340 of FIG. 3. The surrogate model 472 may be trained with simulated data generated by the digital system model 470 of the subsystem of the vehicle 104. The surrogate model 472 may be a low-fidelity, computationally efficient, and/or a physical-based model that approximates the digital system model 470 of the subsystem. An advantage of using the surrogate model 472 to generate simulation data is in its speed. For example, while the digital system model 470 may take a substantially long period of time to execute depending on the complexity of the subsystem, the surrogate model 472 may execute more quickly regardless of the complexity of the subsystem. In some embodiments, the processing unit 474 can execute the surrogate model 472 in less than 0.0005 seconds for a single flight. As such, the surrogate model 472 may efficiently process data, use less memory, and reduce network and CPU consumption, as compared to the digital system model 470 (e.g., a high fidelity model) of the subsystem.

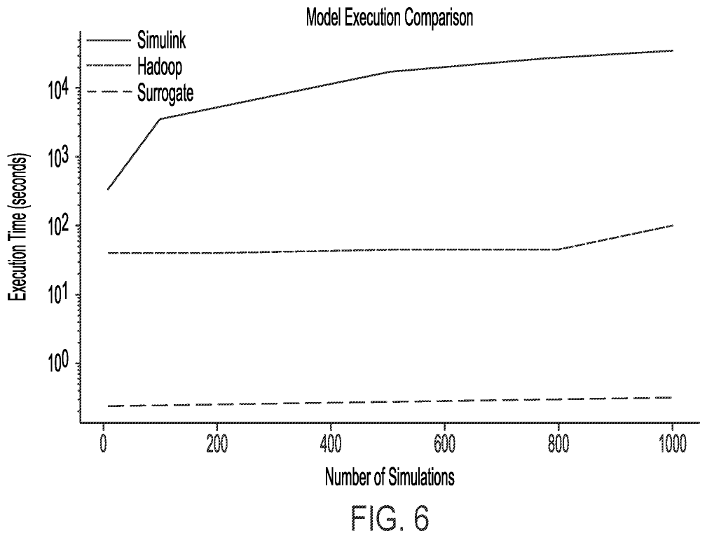

FIG. 6 shows an illustration of the execution times of the surrogate model 472 of the digital system model of an environmental control system of the vehicle 104, the Simulink executable version of the digital system model of the environmental control system, and the Hadoop executable version of the digital system model of the environmental control system. As shown in FIG. 6, the surrogate model may be executed 10 to 100 times faster than the Hadoop execution version of the digital system model of the environmental control system.

The processing unit 474 of the digital twin system 406 may be configured to synchronize or update the digital twins of a subsystems based on the output or simulation data generated by surrogate models. For example, the processing unit 474 may execute the surrogate model 472 of the digital system model 470 to generate estimates of one or more parameters or variables of the subsystem based on actual or historical data (e.g., in-service data) generated by the sensors of the vehicle 104. In some instances, the one or more parameters or variables generated by the surrogate model 472 may relate to unobservable conditions of the subsystem (e.g., conditions that may not be measured or detected directly by the sensors of a subsystem).

Once the surrogate model 472 has generated the model outputs (e.g., simulation data), the processing unit 474 of the digital twin system 406 may update or synchronize the digital twin of the subsystem of the vehicle 104 (e.g., physical asset). For example, the processing unit 474 may execute the digital system model 470 of the subsystem to generate output or simulation data for updating or synchronizing the digital twin of the subsystem. For example, the digital system model 470 of the subsystem may be configured to generate the simulation data based on observable conditions or inputs (e.g., actual or historical operational data or in-service data) and unobservable conditions or inputs (e.g., the estimates of the parameters or variable generated by the surrogate model 472).

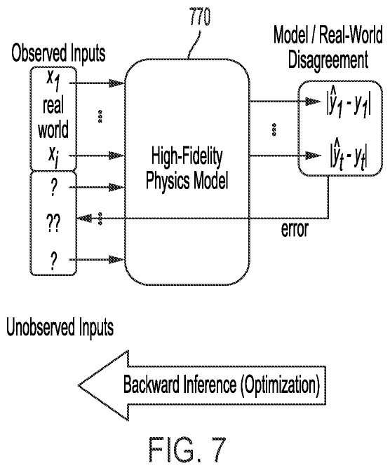

As shown in FIG. 7, the processing unit 474 may execute the digital system model 770 (e.g., a high fidelity physics model) using linear or nonlinear programming techniques to estimate unobserved conditions or inputs by generating the simulation data or model outputs which closely match observed conditions. In some instance, the Hadoop executable version of the digital system model may be executed to generate the simulation data. The simulation data may model or represent the condition or state of the subsystem and may include the state or condition of a subsystem. The processing unit 474 may use the simulation data to update or synchronize the digital twin of the subsystem to correspond to the current state of the subsystem. By using the unobservable conditions (e.g., estimates of the parameters or variables) as inputs into the digital system model 470, the digital system model 470 can be used to quickly and efficiently update the digital twin of the subsystem (e.g., environmental control system 340). As result, the error between the observable model output and the observable real-world data may be minimized. The, the digital twin of the twin may be updated to accurately represent the state or condition from the subsystem (e.g., physical asset).

The processing unit 474 of the digital twin system 406 may monitor and analyze the state or condition of the subsystem based on the digital twin of the subsystem. To evaluate a digital twin of a subsystem, the processing unit 474 may compare the simulated performance data of a subsystem to actual or historical operational performance data of the subsystems. For example, the processing unit 474 may compare the digital twin of a subsystem with parameters and performance data of subsystems during operation with known outcomes. When the processing unit 474 of the digital twin system determines a fault or a degraded condition or state of the subsystem after analyzing the digital twin, the processing unit 474 may take a responsive action, such as by scheduling maintenance for the vehicle 104, notifying an operator, or the like. The processing unit 474 may also use the digital twins to monitor the state or condition of the associated systems, subsystems, and/or components of the vehicle.

The processing unit 474 of the digital twin system 406 may include one or more computer processors and may include a distributed group of computer processors. The processing unit 474 may include, or be implemented on, programmable, reconfigurable, and/or dedicated hardware such as field-programmable gate arrays, digital signal processors, and/or application specific integrated circuits. The processor, the memory, and the input/output device may be operatively coupled to each other by a data bus, a communication interface, and/or a network interface. The communications infrastructure may be configured to transmit and/or to receive signals, such as electrical, electromagnetic, optical, and/or acoustic signals. For example, the communications infrastructure may be configured to manage data link.

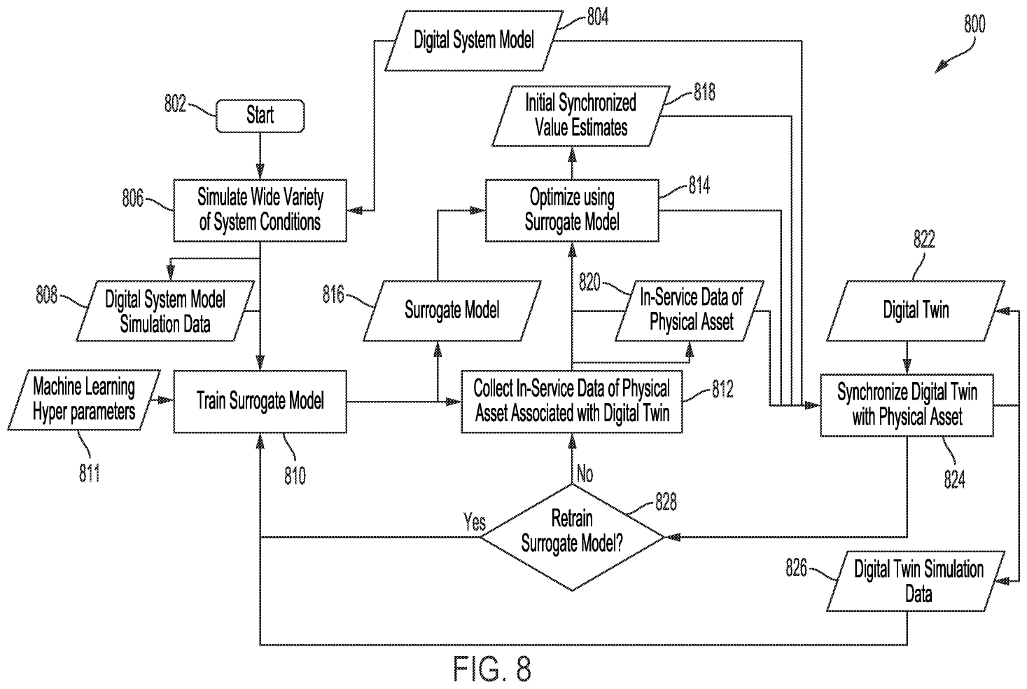

FIG. 8 illustrates a flow chart of a method of updating or synchronizing a digital twin of a subsystem of a vehicle, according to an exemplary embodiment. The method 800 may include one or more operations, functions, or actions, as depicted by one or more of blocks 802-828, each of which may be carried out by any of the systems, methods, or apparatus shown in figures, among other possible systems.

Those skilled in the art will understand that the flow chart described herein illustrates functionality and operation of certain implementations of the present disclosure. In this regard, each block of the flowchart may represent a module, a segment, or a portion of program code, which includes one or more instructions executable by one or more processors for implementing specific logical functions or steps in the process. The program code may be stored on any type of computer readable medium, for example, such as a storage device including a disk or hard drive.

In addition, each block may represent circuitry that is wired to perform the specific logical functions in the process. Alternative implementations are included within the scope of the example implementations of the present application in which functions may be executed out of order from that shown or discussed, including substantially concurrent or in reverse order, depending on the functionality involved, as would be understood by those reasonably skilled in the art.

The method 800 may be performed in whole or in part by a computing or processing device of a digital twin system, such as a processing device similar to or the same as the processing unit 474 of the digital twin system 406 of FIG. 4. In some embodiments, the digital twin system may be part of a computing system located onboard a vehicle, such as a vehicle computing system. In other embodiments, one or more operations of the method 800 can be performed by a processing or computing device that is remote from and wirelessly coupled to a vehicle (e.g., a remote computing system, a server, a cloud computing system). For instance, a server can perform each of the blocks 802-828. In addition, some examples may involve using multiple computing systems, such as a combination of computing systems.

The method 800 may start at block 802. The computing device of a digital twin system may generate or receive a digital system model of a subsystem of a vehicle. At block 804, the computing device of the digital twin system of the subsystem may execute the digital system model to generate simulated data. The digital system model of the subsystem may be a high-fidelity model and/or a physics-based model of the subsystem of the vehicle. In one embodiment, the digital system model may represent or model an environmental control system of an aircraft, such as the environmental control system 340 of FIG. 3.

At block 806, the method may involve simulating a wide variety of system conditions. For example, the computing device of the digital twin system may execute the digital system model based on the simulated data. For example, the computing device of the digital twin system may execute the digital system model based on actual or historical operational or performance data of the subsystem (as detected by the sensors) and/or simulated operational or performance data of the subsystem (as generated by a model of the subsystem). The operational or performance data may include any attribute, condition, feature, behavior, characteristic, or the like that may change over time, such as voltage, current, fluid pressure (e.g., air pressure), temperature, and the like. In one example, the operation or performance data may include sensor data of the subsystem (e.g., an environmental control system) that was acquired over multiple flights of an aircraft.

In one embodiment, the digital twin model may be a model of the environmental control system, such as the environmental control system 340 of FIG. 3. At block 808, the computing device may execute the digital system model of the environmental control system to generate simulated data based on operational or performance data of the system. The simulated data may represent the state or condition of the subsystem of the vehicle. For example, the simulated data may include heat exchanger temperatures, cabin temperatures, air cycle machine temperatures, and the like.

The computing device of the digital twin system may generate an executable version of the digital system model using a MATLAB® Simulink® simulation tool. The Simulink executable version of the digital system model may be exported to run in a Hadoop/Spark computational environment. The computing device may run the Hadoop/Spark executable version of the digital system model in the Hadoop/Spark computational environment to generate simulated data (e.g., simulated performance data) based on operational or performance data of the subsystem. The Hadoop executable version of the digital system model may decrease the execution time to generate the simulated data. In some embodiments, the simulations using the Hadoop executable version may be run in parallel to decrease the time to produce the simulated data. The simulated data may represent the state or condition of the subsystem of the vehicle. The simulated data includes sensor data of the subsystems of the aircraft that were acquired over multiple flights of the aircraft.

At block 810, the method involves training a surrogate model. The computing device of the digital twin system may generate or receive a surrogate model of the digital system model. The surrogate model may be a statistical or mathematical model that approximates the subsystem and may be a reduced version of the digital system model of the subsystem. For example, the surrogate model may be generated using estimation algorithms to process the operational or performance data (e.g., sensor data from sensors of the system). As such, the surrogate model may be a low-fidelity model and/or a physical based model that approximates the behavior of the subsystem.

The surrogate model may be trained based on the simulated data generated by the digital system model and machine learning hyper-parameter values at block 811. For example, the surrogate model can be trained by applying machine learning algorithms to the simulated data generated by the digital system model of the subsystem. In some examples, the training data may include sensor data of the subsystems of the aircraft. Further, the machine learning hyper-parameter values and the simulation data for updating the digital twin may be used to train the surrogate model as further described below. To train the surrogate model, software tools such as TensorFlow, PyTorch, etc., can be used.

At block 812, the method involves collecting in-service data of the physical asset (e.g., subsystem) associated with the digital twin. For example, the computing device of the digital twin system may receive or obtain sensor data detected by the sensors of the subsystems during operation (e.g., actual or historical operational or performance data of the subsystem). The sensor data may represent, for example, pressure, temperature, position, speed, operating state, etc., associated with the subsystem of the vehicle. In some embodiments, the sensor data may include pump speeds, coolant flow rates, cargo loads, route characteristics (e.g., terrain, slope, distance of trip, etc.), operating constraints (e.g., speed, noise, and/or emissions restrictions), environmental conditions (ambient temperature, barometric pressure, altitude, humidity, wind, precipitation, etc.) and the like encountered by the vehicle.

At block 814, the method involves optimizing using the surrogate model. Once the surrogate model is trained, the computing device of the digital twin system may receive the trained surrogate model at block 816. The computing device may execute the surrogate model to generate or produce initial synchronized value estimates at block 818 based on the sensor data (e.g., in-service data) of the subsystem at block 820. For example, the computing device may receive the operational or performance data after the operation of the system of the vehicle (e.g., sensor data acquired over multiple flights of the aircraft). The surrogate model may be executed to generate estimates of conditions or parameters associated with the subsystem (e.g., initial synchronized value estimates) based on the operational or performance data of the subsystem as described above. As further described below, the computing device may execute the digital system model of the subsystem to generate output or simulation data for updating the digital twin of the subsystem. The digital twin system may update the digital twin based on the output or simulation data.

At block 822, the computing device of the digital twin system may generate or receive the digital twin of the subsystem (e.g., physical asset) of the vehicle. The digital twin may be developed or generated during the design, testing, manufacturing, or operational phase of the subsystem and stored in the digital twin system. In some embodiments, the digital twin may be generated by the digital system model of the subsystem. For example, the computing device of the digital twin system may generate the digital twin based on actual or historical operational or performance data received from the sensors of the subsystem or vehicle. The digital twin may be a digital or virtual representation of the subsystem that is indicative of the state or condition of the subsystem of the vehicle. For example, the digital twin may be a representation of an operational or performance state of the subsystem of the vehicle. In some embodiments, the digital twin may represent the subsystem based on its current state or condition.

In one embodiment, the digital twin may be a digital representation of a state or condition of an environmental control system of an aircraft, such as the environmental control system 340 of FIG. 3. For example, the digital twin of the environmental control system subsystem may represent heat exchanger temperatures, cabin temperatures, air cycle machine temperatures, and the like. Although the digital twin system may generate a digital twin for the environmental control system of the vehicle, it will be recognized that the digital twin system may also generate digital twins for other subsystems of the vehicle as well for subsystems of other vehicles in the fleet.

At block 824, the digital twin system may synchronize the digital twin with the physical asset (e.g., subsystem). The digital twin system may be configured to update or synchronize the digital twin to correspond to the current state of the subsystem based on updated or new actual operational or performance data obtained about the subsystem. For example, the computing device may execute the digital system model of the subsystem to generate digital twin simulation data at block 826 for updating the digital twin of the subsystem based on the in-service data of the subsystem and the initial synchronized value estimates generated by the surrogate model. The computing device may execute a Hadoop/Spark executable version of the digital system model to generate the digital twin simulation data.

At block 828, the method may involve determining whether to retrain the surrogate model. If the digital twin system determines that the surrogate need to be trained, the method proceeds to block 810. When training the surrogate model, the digital twin simulation data, generated by the digital system model of the system, may be used. If the surrogate model does not need to be trained, the method may proceed to block 812 to collect in-service data of the subsystem.

While the systems and methods of operation have been described with reference to certain examples, it will be understood by those skilled in the art that various changes can be made and equivalents can be substituted without departing from the scope of the claims. Therefore, it is intended that the present methods and systems not be limited to the particular examples disclosed, but that the disclosed methods and systems include all embodiments falling within the scope of the appended claims.

1. A system comprising:
a memory; and
a processor in communication with the memory, wherein the processor is configured to:
receive a digital system model of a system of a vehicle or machine;
execute the digital system model based on simulated conditions to generate simulated data;
train a surrogate model using at least the simulated data to approximate the digital system model of the system;
generate, using the trained surrogate model, estimated values for conditions or parameters of the systems based on operational data, wherein the operational data includes sensor data or in-service data from the system;
execute the digital system model of the system to generate simulation data based on the operational data and the estimated values or parameters generated by the surrogate model; and
synchronize or update a digital twin of the system based on the simulation data, wherein the digital twin represents a state or condition of the system.

2. The system according to claim 1, wherein the synchronized or updated digital twin corresponds to a current state or condition of the system of the vehicle.

3. The system according to claim 1, wherein the digital system model includes a physics-based model of the system.

4. The system according to claim 1, wherein the estimated values of the conditions or parameters of the system are generated by the surrogate model to minimize an error between an output of the digital system model and real-world data.

5. The system according to claim 1, wherein the conditions or parameters of the system are unable to be measured or detected directly by a sensor of the system.

6. The system according to claim 1, wherein the processor is further configured to use computation techniques to synchronize or update the digital twin of the system.

7. The system according to claim 1, wherein the digital system model is implemented in a Hadoop/Spark computational environment.

8. The system according to claim 1 wherein the processor is further configured to train the surrogate model based on machine learning hyper-parameter values and the simulation data.

9. The system according to claim 1, wherein the surrogate model comprises a machine learning model, a physics-based model, a neural network, or a combination thereof.

10. The system according to claim 1, wherein the digital system model includes a model of an environmental control system, and wherein the system includes an environmental control system.

11. The system according to claim 1, wherein the processor executes the surrogate model substantially faster than the digital system model.

12. The system according to claim 1, further comprising a display device configured to display the synchronized or updated digital twin of the system of the vehicle or machine.

13. The system according to claim 1, wherein the vehicle is an aircraft, wherein the system comprises a subsystem or component, and wherein the operational data includes operating historical data of the system of the vehicle.

14. A method comprising:
receiving, by one or more processors, a digital system model representing a system of a vehicle or machine;
executing, by the one or more processors, the digital system model based on simulated conditions to generate simulated data;
training, by the one or more processors, a surrogate model using at least the simulated data to approximate the digital system model;
generating, using the trained surrogate model, estimated values for conditions or parameters of the system based on operational data, wherein the operational data includes sensor data or in-service data from the system;
executing, by the one or more processors, the digital system model of the system to generate simulation data based on the operational data and the estimated values for the conditions or parameters generated by the surrogate model; and
synchronizing or updating, by the one or more processors, a digital twin of the system based on the simulation data, wherein the digital twin represents a state or condition of the system.

15. The method according to claim 14, wherein the synchronized or updated digital twin corresponds to a current state or condition of the system of the vehicle or machine.

16. The method according to claim 14, wherein the digital system model includes a physics-based model of the system.

17. The method according to claim 14, wherein the estimated values for the conditions or parameters of the system are generated by the surrogate model to minimize an error between an output of the digital system model and real-world data.

18. The method according to claim 14, further comprising training the surrogate model based on machine learning hyper-parameter values and the simulation data.

19. The method according to claim 15, further comprising displaying the synchronized or updated digital twin representing the state or condition of the system of the vehicle or machine.

20. A non-transitory computer-readable medium having stored thereon instruction code, wherein the instruction code is executable by a processor of a computer to perform operations comprising:
receiving a digital system model representing a system of a vehicle or machine;
executing the digital system model based on simulated conditions to generate simulated data;
training a surrogate model using at least the simulated data to approximate the digital system model;
generating, using the trained surrogate model, estimated values for conditions or parameters of the system based on operational data, wherein the operational data includes sensor data or in-service data from the system;
executing the digital system model of the system to generate simulation data based on the operational data and the estimated values for the conditions or parameters generated by the surrogate model; and
synchronizing or updating a digital twin of the system based on the simulation data, wherein the digital twin represents a state or condition of the system.
